(19) United States
(12) Patent Application Publication
(10) Pub. No.: US 2021/0057556 A1
(43) Pub. Date: Feb. 25, 2021

(54) IGBT DEVICES WITH 3D BACKSIDE STRUCTURES FOR FIELD STOP AND REVERSE CONDUCTION

(71) Applicant: IPOWER SEMICONDUCTOR, GILROY, CA (US)

(72) Inventor: HAMZA YILMAZ, GILROY, CA (US)

(73) Assignee: IPOWER SEMICONDUCTOR, GILROY, CA (US)

(21) Appl. No.: 17/092,267

(22) Filed: Nov. 7, 2020

Related U.S. Application Data
(62) Division of application No. 16/270,233, filed on Feb. 7, 2019, now abandoned.
(60) Provisional application No. 62/627,726, filed on Feb. 7, 2018.

(51) Int. Cl. H01L 29/739; H01L 29/40; H01L 29/66; H01L 21/308; H01L 29/06; H01L 21/265; H01L 27/07

(52) U.S. Cl. CPC H01L 29/7397; H01L 29/402; H01L 29/66348; H01L 27/0727; H01L 29/0634; H01L 21/26506; H01L 27/0716; H01L 21/308

(57) ABSTRACT

A vertical IGBT device is provided. The vertical IGBT device includes a substrate having a first conductivity type. A drift region of the first conductivity type formed on the top surface of the substrate. The bottom surface of the substrate is patterned to have an array of mesas and grooves. The mesas and the grooves are formed in an alternating fashion so that each mesa is separated from the other by a groove including a groove surface. In the groove surface, a top buffer region of the first conductivity type and a bottom buried region of a second conductivity type are formed extending laterally between the mesas adjacent each groove surface. Each mesa includes an upper region of the first conductivity and a lower region of the second conductivity.

### CROSS REFERENCE TO RELATED APPLICATION

This application is a divisional patent application of U.S. patent application Ser. No. 16/270,233 filed on Feb. 7, 2019 which claims priority from U.S. provisional patent application No. 62/627,726 filed on Feb. 7, 2018, which are expressly incorporated by reference herein in their entirety.

### BACKGROUND

### Field of the Invention

The present invention relates to insulated gate semiconductor devices, more particularly, to device structures and methods of forming insulated gate bipolar transistor (IGBT) semiconductor devices.

### Description of the Related Art

An insulated-gate bipolar transistor (IGBT) device is a wide base pnp bipolar junction transistor (BJT) device driven by a MOSFET. The IGBT devices have become a key power device in handling high current and high voltage motor control and induction heating type applications. In order to further improve IGBT efficiency and robustness, there is a continuous research and development to reduce forward voltage drop (Vce-Sat) and to minimize the switching losses as well as to improve safe operation area (SOA) of an IGBT device.

Forward voltage drop (Vce-Sat) may be reduced, for example, by the following: (a) a low MOSFET resistance which provides the base current for vertical PNP BJT; (b) spreading the resistance amongst MOSFET cells at the upper portion of the IGBT; (c) high levels of carrier modulation in wide n− base region of the PNP which is impacted by minority carrier life time and the injection efficiency.

Unfortunately high levels of carrier modulation or carrier storage may also increase switching losses by slowing turning off speed and degrade SOA of IGBT devices. Another tradeoff between the low voltage MOSFET drain and source resistance, rds which usually results in higher saturation and shorter withstand time during the mode of load short circuit for motor drive applications. Base to source shorting of parasitic NPN BJT as part of a MOSFET is very critical to prevent latch up and enhance IGBT device robustness.

### SUMMARY

An aspect of the present invention includes a vertical IGBT device structure, including: a substrate having a top surface and a bottom surface, the substrate having a first conductivity type; and a drift region of the first conductivity type formed on the top surface; wherein the bottom surface is patterned to have an array of mesas and grooves in the substrate which are placed in alternating fashion so that each mesa is separated from the other by a groove including a groove surface in which a top buffer region of the first conductivity type and a bottom buried region of a second conductivity type are formed extending laterally between the mesas adjacent each groove surface, and wherein each mesa includes an upper region of the first conductivity and a lower region of the second conductivity, and wherein the top buffer region of the first conductivity type is an n type buffer region and the bottom buried region of the second conductivity type is a p+ hole injection region.

Another aspect of the present invention includes a vertical IGBT device structure, including: a substrate having a top surface and a bottom surface, the substrate having a first conductivity type; a drift region of the first conductivity type formed over the top surface; and a buffer layer of the first conductivity type formed extending between the drift region and the top surface of the substrate; wherein the bottom surface is patterned to have an array of mesas and grooves in the substrate which are placed in alternating fashion so that each mesa is separated from the other by a groove including a groove surface exposing a portion of the buffer layer, a buried region of a second conductivity type formed, in the portion of the buffer layer exposed by the groove surface, extending laterally between the mesas adjacent each groove surface, wherein the buried region is a p+ hole injection region.

Another aspect of the present invention includes a process for forming vertical IGBT devices, including: finalizing a front surface process on a front surface of a semiconductor wafer, wherein the front surface process forms a front surface structure; and forming a backside structure on the semiconductor wafer, including: thinning a back surface of the semiconductor wafer down to a predetermined thickness; implanting dopants to mesa regions defined on the back surface; patterning and etching a back surface of the wafer to form an array of mesas and grooves in the back surface which are formed in alternating fashion so that each mesa is separated from the other by a groove including a groove surface; implanting dopants of a first conductivity and a second conductivity to the back surface to form buried regions inside the groove surfaces; activating the buried regions and the mesa regions, depositing a back metal layer conformally coating the mesas and grooves, and filling the grooves between the mesas with solder material, wherein the top buffer region of the first conductivity type is an n type buffer region and the bottom buried region of the second conductivity type is a p+ hole injection region.

Another aspect of the present invention includes a process for forming vertical IGBT devices, including: finalizing a front surface process on a front surface of a semiconductor wafer, wherein the front surface process forms a front surface structure including performing contact etching followed by a contact coating step for coating the contacts with a protection layer including silicon nitride; forming a backside structure on the semiconductor wafer, including: thinning a back surface of the semiconductor wafer down to a predetermined thickness; implanting dopants to mesa regions defined on the back surface; patterning and etching a back surface of the wafer to form an array of mesas and grooves in the back surface which are formed in alternating fashion so that each mesa is separated from the other by a groove including a groove surface; implanting dopants of a first conductivity and a second conductivity to the back surface to form buried regions inside the groove surfaces; activating the buried regions and the mesa regions, depositing a back metal layer conformally coating the mesas and grooves, and filling the grooves between the mesas with solder material; and removing the protection layer coating the contacts on the front surface; depositing a front side metal; and passivating the device.

Yet another aspect of the present invention includes a vertical IGBT device structure, including: a substrate of a single crystal drift region of an n− type; and a bottom surface of the substrate is patterned to have an array of mesas and grooves in the substrate which are placed in alternating fashion so that each mesa is separated from the other by a groove including a groove surface, wherein each mesa and each groove surface include a hole injection region of p+ type, wherein the array of mesas and grooves are conformally coated with a back metal layer including one of a Ti/Ni/Ag layer and an Al/Ti/Ni/Ag layer, and wherein a solder material is deposited on the back metal layer to fill the grooves.

### BRIEF DESCRIPTION OF THE DRAWINGS

FIG. 1A is a schematic view of an IGBT structure, in one embodiment, including trench MOSFET cells with p+ poly and p-columns;

FIG. 1B is a schematic view of an IGBT structure, in one embodiment, including gate metal and n+ poly silicon contact region;

FIG. 1C is a schematic view of an IGBT structure, in another embodiment, including p+ poly with p side wall shield as another embodiment;

FIG. 2A is a schematic view of an IGBT structure including high voltage (HV) termination region;

FIG. 2B is a schematic view of an IGBT structure including a channel region after a last p ring of HV termination region;

FIG. 3A is a schematic view of an IGBT having a 3D backside structure including backside implanted n field stop and buried p+ with n−/p+ mesa injection region;

FIG. 3B is a schematic view of a RC-IGBT having a 3D backside structure including backside implanted n field stop and buried p+ with n−/n+ mesa diode;

FIG. 3C is a schematic view of a RC-IGBT having a 3D backside structure including backside implanted n field stop and buried p+ with depletable p−/n+ mesa diode;

FIG. 3D is a schematic view of a RC-IGBT, in another embodiment, having a 3D backside structure including a uniform n buffer, buried p+ injection region with n−/n+ mesa diode with dielectric spacer;

FIG. 3E is a schematic view of a RC-IGBT, in another embodiment, having a 3D backside structure including a uniform n buffer, buried p+ injection region with n−/n+ mesa diode;

FIG. 3F is a schematic view of an IGBT, in another embodiment, having a 3D backside structure including a uniform n buffer with buried p+ poly silicon injection region;

FIG. 4A is a schematic view of an IGBT having a 3D backside structure including an n− substrate;

FIG. 4B is a schematic view of an IGBT having a 3D backside structure including an n− substrate after the step of thinning and etching the backside using a mask;

FIG. 4C is a schematic view of an IGBT having a 3D backside structure including an n− substrate after the step of n buffer and p+ hole injector are formed;

FIG. 4D is a schematic view of an IGBT having a 3D backside structure including an n− substrate after the step of back metal deposition;

FIG. 4E is a schematic view of an IGBT having a 3D backside structure including an n− substrate after an alternative step of filling the backside with solder using the stencil approach;

FIG. 4F is a schematic view of a RC-IGBT having a 3D backside structure including an n−substrate after the step of back metal deposition;

FIG. 4G is a schematic view of a RC-IGBT having a 3D backside structure including oxide spacers;

FIG. 4H is a schematic view of a RC-IGBT having a 3D backside structure including the backside solder;

FIG. 5A is a schematic view of an RC-IGBT having a 3D backside structure including depletable p−/n+ diode;

FIG. 5B is a schematic view of an IGBT having a 3D backside structure including a p− substrate with back metal;

FIG. 5C is a schematic view of a RC-IGBT having a 3D backside structure including depletable p−/n+ diode;

FIG. 6A is a schematic view of an IGBT having a 3D backside structure including an n buffer and n− substrate;

FIG. 6B is a schematic view of an IGBT having a 3D backside structure including an n buffer and n− substrate, after processing the backside and depositing back metal;

FIG. 6C is a schematic view of an IGBT having a 3D backside structure including an n buffer and n− substrate, after depositing solder over the back metal;

FIG. 6D is a schematic view of an IGBT having a 3D backside structure including an n buffer and n− substrate with n+ electron injection region; and

FIG. 6E is a schematic view of a RC-IGBT having a 3D backside structure including an n buffer and n− substrate, after back metal and solder depositions.

### DETAILED DESCRIPTION

To control and optimize the carrier injection efficiency, the structure of a hole injector (hole injection region), which is the backside of the vertical IGBT device, is very critical. The backside of the IGBT device structure is not only critical for the carrier injection efficiency and switching performance, but it is also critical for integrating a free wheeling diode (FWD) with an IGBT device to eliminate the external FWD in parallel with the IGBT in the inductive load type applications. An integrated FWD and IGBT device structure is called reverse conducting (RC) IGBT. An RC-IGBT may show negative resistance effect in its collector emitter current-voltage (I-V) characteristics which can create undesirable effects in the application, if it is not specifically designed to minimize or prevent it (the negative resistance effect).

The present inventions provide embodiments of robust and efficient IGBT device structures by optimizing Vce-Sat, turn off speed and safe operation area (SOA) by spreading resistance reduction, controlling carrier injection and forming deeper junctions by employing poly silicon filled trenches.

Embodiments of the present invention described below may include backside structures including 3D (three dimensional) backside structures including, for example, 3D hole injector structures, for IGBT devices and RC-IGBT devices. The 3D hole injector structures of the present invention may enable: (a) formation of an optimized field stop (FS) IGBT device backside structure by etching down certain portion of the backside of a thicker wafer or substrate; (b) integration of a free wheeling diode (FWD) structure with an optimized FS IGBT structure with minimal negative resistance effect in its collector-emitter (I-V) characteristics.

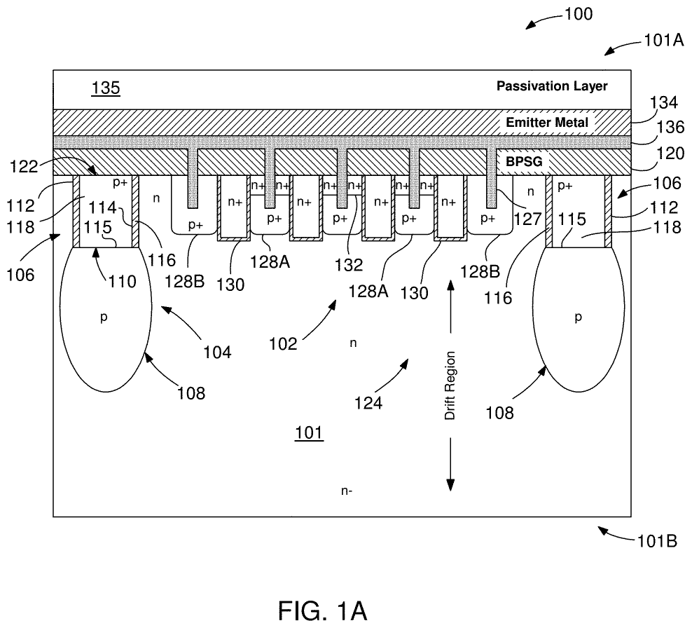

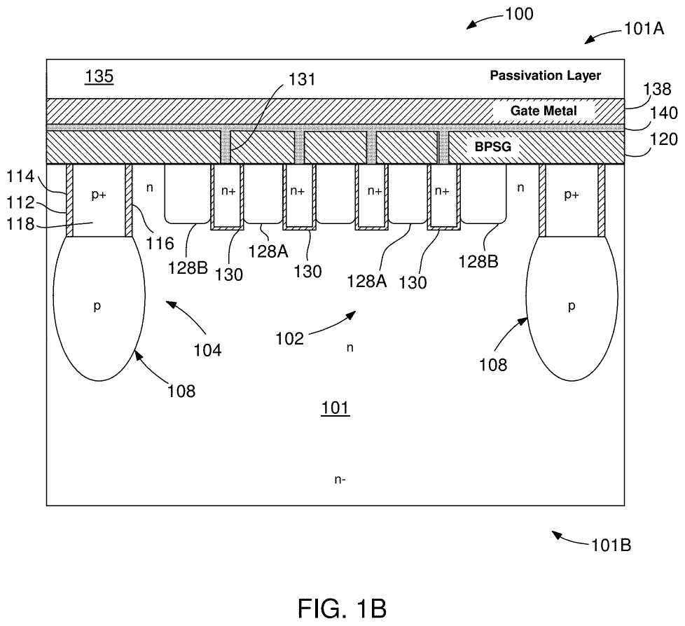

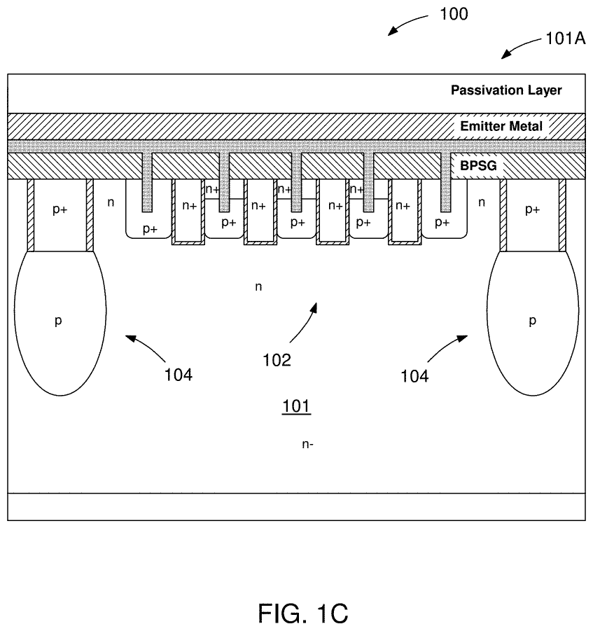

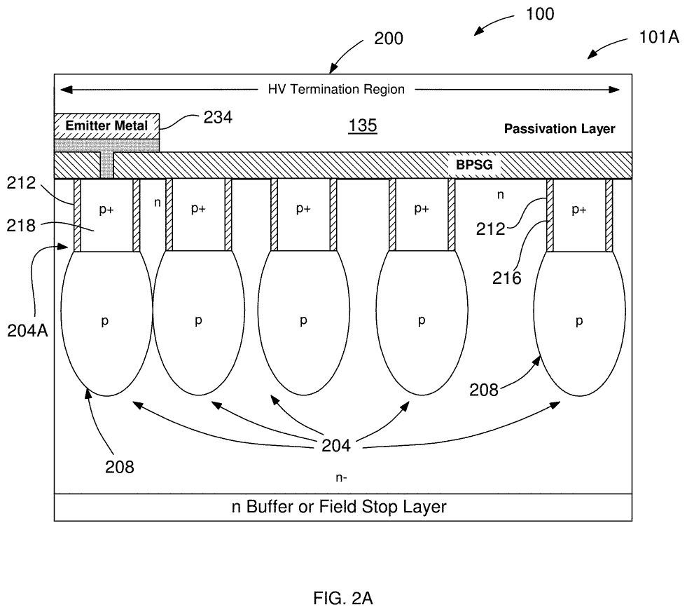

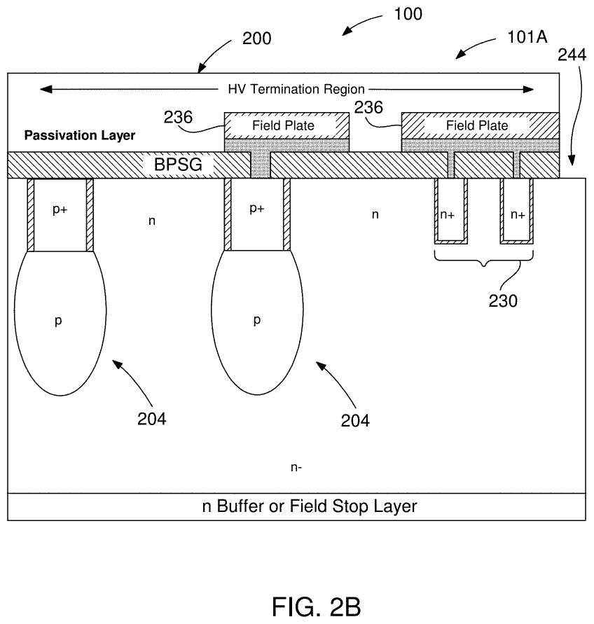

In one embodiment, 3D backside structures of the present invention may be formed after completing a front side forming processes on the same wafer or the substrate. Accordingly, an exemplary starting wafer may have an IGBT device structure on the top surface or the front surface having an active device area and HV termination area as shown in FIGS. 1A-1C and FIGS. 2A-2B respectively. In other embodiments, however, 3D backside forming processes may begin before the completion of the front side forming processes or before initiating the front side forming process and this aspect is also within the scope of this invention.

In the below device embodiments, the front side may include any vertical IGBT device structure including trench and planar IGBT device structures.

FIG. 1A shows an embodiment of an IGBT with front side structure including trench MOSFET cells and deep p columns including p+ poly silicon (Si) filled trenches and p regions extending from the trenches into the semiconductor substrate of the IGBT. Turning now to the Figures, FIG. 1A illustrates an embodiment of a vertical IGBT cell 100 formed in an n− type semiconductor substrate 101, or a base region 101, and at a front side 101A of the semiconductor substrate. The base region 101 may be a single crystal semiconductor of n-type conductivity (first type conductivity), for example n-type silicon semiconductor, or an n type epitaxial layer grown on a semiconductor wafer or a substrate. A center portion of the IGBT cell 100 may include an array of MOSFET cells 102 connected in parallel. For purposes of clarity a reduced number of MOSFET cells 102 are used in the cross sectional FIGS. 1A-1B.

An edge region of the IGBT cell 100 may include a column 104, or a column structure 104, fully and continuously surrounding the MOSFET cells 102. The column 104 may have p-type conductivity or second type conductivity. There may be multiple column structures 104, which are concentrically surrounding or enclosing the active area and the array of MOSFET cells 102 for the high voltage protection of the MOSFET cells. In FIGS. 1A and 1B, the column 104 is used for high voltage (HV) protection of the MOSFET cells 102. The MOSFET cells 102 may be trench MOSFET cells in this embodiment. The column 104 may include a column base 106 connected to a buried region 108 (implanted region) or a deep region 108 via a trench interface 110. The column base 106 may include a column trench 112 having trench side walls 114 and trench floor 115 defining the column trench 112. The column trench 112 may include a trench spacer 116 or a spacer 116 formed on the trench side walls 114 and a trench filler 118 filling the column trench 112 which is in contact with a dielectric layer 120, such as an BPSG layer, via a column interface 122. A drift region 124 within the base region 101 may extend from the trench MOSFET cells 102 and along the base region 101 to the backside 101B.

The trench MOSFET cells 102 may include p-body contact regions 128 including p-body contacts 127. The p-body contact regions 128 may be separated from one another by gate contact trenches 130 or gate trenches 130 for gate contacts 131 (shown in FIG. 1B). The gate trenches 130 may be filled with n+ poly silicon (n+ poly Si contact regions). The p-body contact regions 128 may have inner p-body contact regions 128A and outer p-body contact regions 128B, both of which are heavily p doped. The inner p-body contact regions 128A may include n+ emitter contact regions 132. The emitter metal 134 may be connected to the n+ emitter contact regions 132 and p-body contact regions 128 by a Ti/TiN/W buffer metal 136 extending through the dielectric layer 120, thereby forming the p-body contacts 127 extending into the p-body contact regions 128. A passivation layer 135 may coat the front side 101A.

In one embodiment, the trench filler 118 of the column 104 may be p+ poly silicon material and the deep region 108 may be a p-region, p type implant implanted deep region, or a deep p-region. The deep regions 108 of the IGBT structure may be floating electrically, i.e., they have no direct ohmic contact to any electrode. Here, p+ denotes a high p type dopant material, such as boron (B), concentration, and p denotes a lower p-type dopant material concentration. Since both the column base 106 and the deep region 108 include p type dopants, the columns 104 may be called p-columns. In one embodiment, the deep regions 108 may be formed by implanting high energy boron implants through the floor 115 of the column trenches 112 that may be formed in the base material 101 which is n type silicon. The spacers 116 may be oxide spacers formed on the trench side walls 114 by oxidizing the trench sidewalls 114 and the column trench 112 is filled with the trench filler 118, i.e., p+ poly silicon (p+ poly Si). High energy p ion implanted deep regions 108 of the columns 104 may be in direct contact with the p+ poly Si trench filler 118.

The spacers 116 may confine the lateral diffusion of boron in the column trench 112 and may keep the column's deep region 108 in its bulb-shape which may be narrow at the top and wide at the bottom adjacent the trench interface 110. The columns 104 may be formed 5 to 20 micrometers (μm) apart from each other depending on the n doping concentration of the base region 101, thus the spacing of the columns 104 may depend on the voltage rating of the IGBT device.

The column 104 is formed in the active area of the IGBT unit cell 100, which is a region of the device inner portion of the HV edge termination region, encircling the MOSFET cells 102 (planar MOSFETs or trench MOSFETs). When IGBT cell 100 is in off-state (voltage blocking mode), the column 104 pinch off below the breakdown of the MOSFET cells 102 which are being encircled by the column 104 (not shown). Accordingly this may demonstrate how IGBT devices having shallow p-body diffusions and shallow trenches may support very high voltage blocking (equal or greater than 1000 V).

The columns 104 may electrically float to improve carrier modulation just below the active IGBT cells to reduce on state voltage across collector-emitter (Vce-Sat) thus reduce power dissipation of the IGBT device. P+ poly Si trench filler 118 is directly in contact with the deep P region 108 and indirectly in contact with drift region 124 of the IGBT cell 100, and thus the trench filler 118 may act like a defect gathering center which may improve carrier life and reduce IGBT device leakages. The direct contact between the deep p region 108 and indirect contact between the drift region 124 and the trench filler 118 may be established through the trench floor 115.

In an embodiment, the contacts in the p-body regions 128 and the n+ emitter regions 132 may be self-aligned to the gate trenches 130 and filled with buffer metal, Ti/TiN/W after forming the contact openings. P+ implant does not impact threshold voltage (VT) of the IGBT device.

FIG. 1B shows the front side structure of the IGBT including gate metal and n+ poly Si contact region. A gate metal 138 is connected to the gate trenches 130 via a Ti/TiN/W buffer metal 140 extending through the dielectric layer 120. The gate trenches 130 include n+ poly Si. Gate contacts 131 to n+ poly Si may be planar type, not trench type, because the gate contact forming step may only include the etching of the BPSG dielectric layer 120. The gate contact forming step may not include Si etching process.

FIG. 1C shows another embodiment of the present invention including a front side structure of an IGBT device structure including a buffer layer 103, or a field stop layer 103, at the bottom of the base region 101. The buffer layer 103 is also a single crystal semiconductor of n type conductivity, for example an n type silicon semiconductor, or an n type epitaxial layer grown on a semiconductor wafer or a substrate. In an embodiment, the n buffer layer 103 may be first grown on a silicon wafer or a substrate, which is followed by growing the lightly doped n− base region 101. In this alternative embodiment, at the front side 101A, the IGBT cell 100 including trench MOSFET cells 102 fully surrounded and protected by the column structure 104 without oxide spacers at the trench side walls 114. The p+ poly Si in the column trench 112 may be shielded by forming sidewall shields 116A on the trench side walls 114 by implanting a p-type dopant thereon. The side wall shields 116A may prevent depletion during the HV blocking state of the IGBT device to avoid high leakage due to the poly silicon's large EHP (electron-hole pair) generation at the poly crystal silicon boundaries.

FIGS. 2A-2D illustrate an embodiment of an exemplary high voltage (HV) termination region 200 used for encircling the active MOSFET cell array at the front side 101A. The HV termination region 200 may be formed using p type column structures (for an n-type semiconductor) having varying separation distances between them.

As shown in FIG. 2A, in one embodiment, column structures 204 in the HV termination region 200 may fully encircle the active device region by forming concentric column rings (not shown). A first p-column ring 204A may be shorted to the emitter metal 234 to drain out stored charge in the HV termination region 200. After forming the first column ring 204A, other column rings 204 may be formed while increasing space between them to minimize surface electric field to achieve minimum area for high voltage termination. Further, p+ poly Si filler 218 within the column trench 212 is confined by the oxide spacers 216 to prevent p+ dopant sideway diffusion to save area and establish voltage division by deep p-regions 208. The deep p-regions 208 are connected to p+ poly Si filling the column trench 212 to minimize surface electric field sensitivity due to external charge from the package and the assembly environment.

FIG. 2B shows, in one embodiment, a channel region after the last p-column ring of HV termination region of the IGBT front side. At a distal edge of the HV termination region 200 adjacent to a saw street 244, MOS cells 230 in contact with field plates 236 are placed to stop HV depletion reaching the die edge, or substrate edge, (sawn region), thereby preventing and leakage current. Field plates 236 are conductors used over a dielectric to help reduce surface electric field.

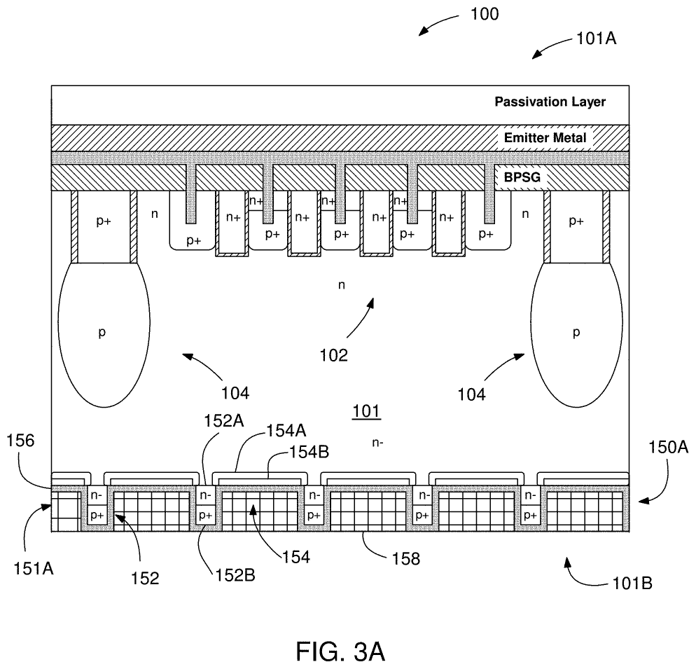

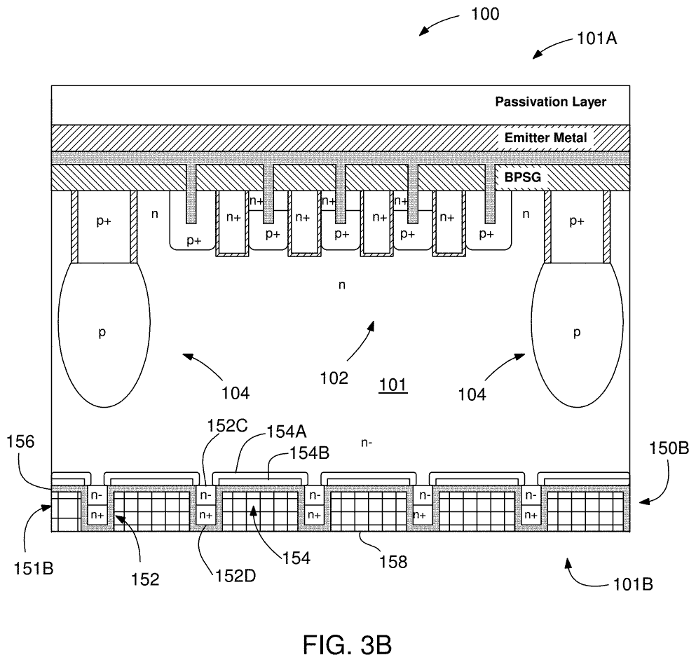

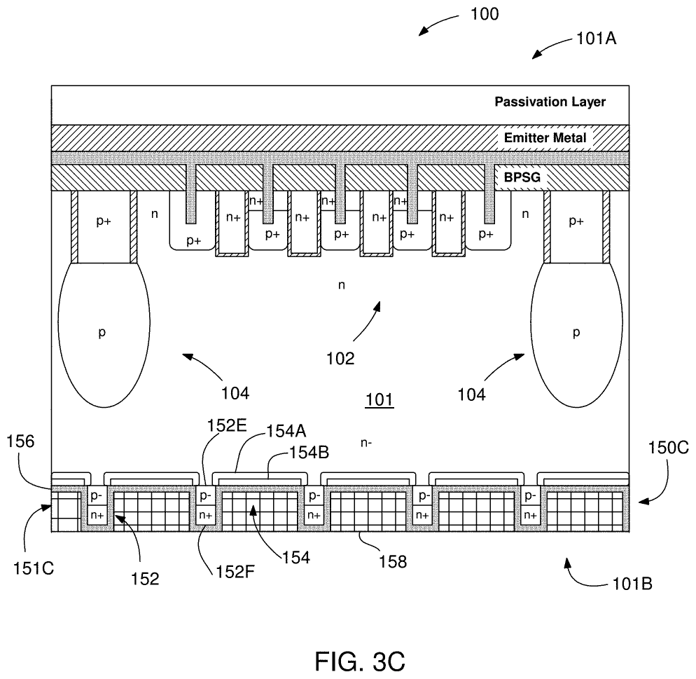

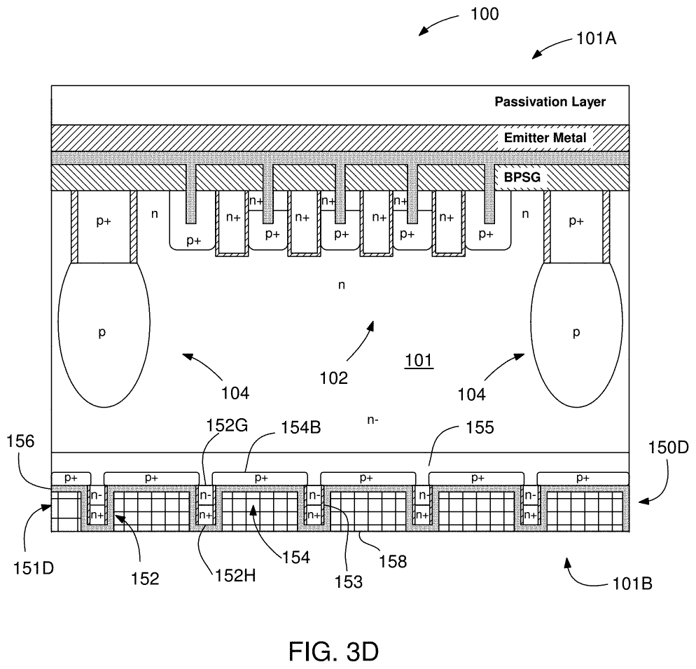

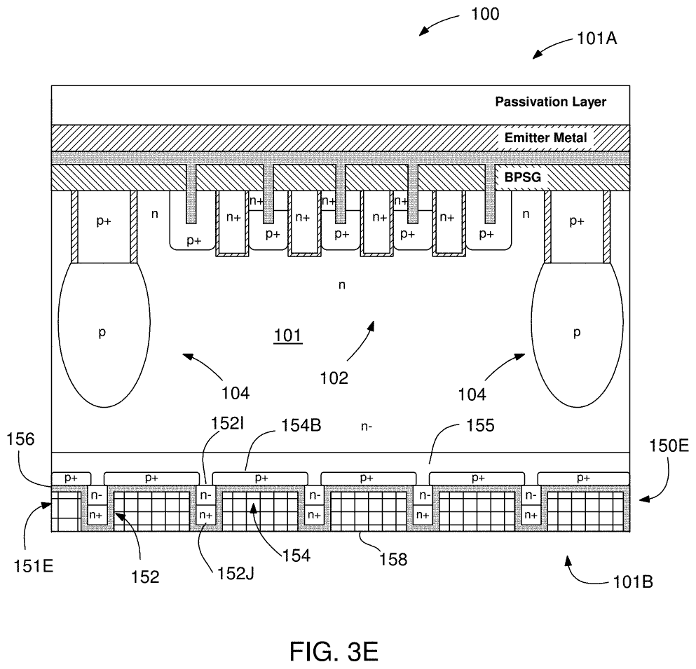

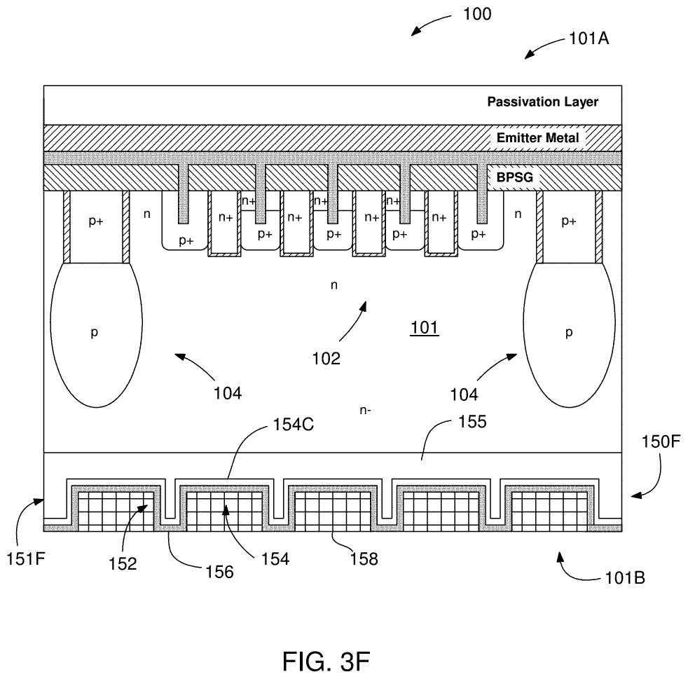

FIGS. 3A-3F illustrate embodiments of 3D backside structure of the present invention to improve IGBT device performance. To control the carrier injection, lower Vce-Sat and Reverse Conducing IGBT (RC-IGBT) construction, wafer backside structure is as important as the front side structure of the wafer. The 3D backside structures described hereinafter will be referred to as the backside structures and may be formed after the completion of the exemplary front side structures described above.

FIG. 3A shows a backside 101B of IGBT device 100 after a backside structure 150A is completed. The backside structure 150A may include mesas 152 and grooves 154 formed by grinding and etching a substrate 151A on which the base region 101 including the above described exemplary front side structures. The substrate 151A may be an n− conductivity type silicon substrate (n− substrate). In one embodiment, the substrate 151A may also be etched down from the wafer backside to a desired thickness to form a field stop (FS) layer depending on the IGBT breakdown voltage. In the backside structure 150A, a first mesa region 152A, or an upper mesa region 152A and a second mesa region 152B, or a lower mesa region 152B, may be formed in the mesas 152 by implanting dopants. The upper mesa region 152A and the lower mesa region 152B form a n−/p+ mesa injection region. The upper mesa regions 152A may have n− type conductivity formed by implanting n type dopants, for example, by implanting phosphorous (P); and the lower mesa regions 152B may have p+ type conductivity by heavily implanting p type dopants to form a p+ type regions, for example, by implanting boron (B). Further, in the backside structure 150A, field stop regions 154A, or buffer regions 154A, and hole injection regions 154B, or buried p+ regions 154B, may be formed in the grooves 154 by implating dopants. The field stop regions 154A may be formed by implanting n type dopants, for example, P; and the hole injection regions 154B may be formed by heavily implanting p type dopants to form a p+ type conductivity regions, for example, by implanting B. A back metal layer 156 including Al/Ti/Ni/Ag or Ti/Ni/Ag layers may conformally coat the mesas 152 and the grooves 154 of the backside structure 150A. A solder layer 158 may be formed on the back metal layer 156 which may fill the grooves 154 with the solder material. The solder layer 158 may be planarized after depositing it, which step may complete the backside structure 150A. The wafer may be sawn from the backside to prevent die cracks after completion of solder planarization.

FIG. 3B shows an embodiment of the IGBT device 100 constructed as a reverse conducting IGBT device (RC-IGBT) with the backside structure 150B including the mesas 152 and grooves 154 formed by grinding and etching a substrate 151B on which the base region 101 including the above described exemplary front side structures. The substrate 151B may be an n− conductivity type silicon substrate (n− substrate). In one embodiment, after the substrate 151B is thinned down, an n+ region is formed by implanting n type dopant element, for example, arsenic

(As) and then Si substrate may be etched using an appropriate mask to form RC-IGBT. The backside structure 150B include the buffer regions 154A having n type conductivity and the hole injection regions 154B having p+ type conductivity formed in the grooves 154 by implating dopants as described in the previous embodiment. Differing from the previous embodiment shown in FIG. 3A, in this embodiment, upper mesa regions 152C may have n− type conductivity formed by implanting n type dopants by implanting p ions; and lower mesa regions 152D may have n+ type conductivity by heavily implanting n type dopants to form a n+ type regions. The upper mesa region 152C and the lower mesa region 152D may form a n−/n+ mesa diode forming RC-IGBT. Accordingly, n+/n− mesa diode regions may form the reverse conduction region to construct RC-IGBT structure of the present invention. In the following step, the back metal 156 and the solder 158 is deposited over the backside as described above in FIG. 3A.

FIG. 3C shows an embodiment of the IGBT device 100 constructed as a reverse conducting IGBT device (RC-IGBT) with the backside structure 150C including the mesas 152 and grooves 154 formed by grinding and etching a substrate 151C on which the base region 101 including the above described exemplary front side structures. In one embodiment, a starting silicon wafer may include a base region 101 including an n− type epitaxial layer formed on the substrate 151C which may be a p− or p type conductivity silicon substrate where the mesas 152 and the grooves 154 are formed. In one embodiment, the substrate 151C with p− type conductivity may be etched down by forming mesas to an n buffer required thickness range depending on the blocking voltage and then an n+ electron injection region may be formed. As a result, in this embodiment, upper mesa regions 152E may have p− type conductivity; and lower mesa regions 152F may have n+ type conductivity by heavily implanting n type dopants. The backside structure 150C may also include the buffer regions 154A having n type conductivity and the hole injection regions 154B having p+ type conductivity formed in the grooves 154 by implating dopants as described in the previous embodiment. Accordingly, n+/n− mesa regions may form the reverse conduction region to construct RC-IGBT structure of the present invention. In the following step, the back metal 156 and the solder 158 is deposited over the backside as described above in FIG. 3A. After depositing the back metal 156 and the solder layer 158, an n+p−n structure may form. The n+p−n structure may deplete p− region and may start injecting electrons when the back metal 156 (collector) is negatively biased, hence this backside structure 150C functions as a diode.

FIG. 3D shows an embodiment of the IGBT device 100 constructed as a reverse conducting IGBT device (RC-IGBT) with the backside structure 150D including the mesas 152 and grooves 154 formed by grinding and etching a substrate 151D on which the base region 101 including the above described exemplary front side structures. In one embodiment, a starting silicon wafer may include a base region 101 including an n− type epitaxial layer and a field stop layer 155 of n type conductivity formed on the substrate 151D which may be a n− type conductivity silicon substrate where the mesas 152 and the grooves 154 are formed. In one embodiment, the substrate 151D may be etched down by forming mesas to form n+ electron injection regions. As a result, in this embodiment, upper mesa regions 152G may have n− type conductivity; and lower mesa regions 152H may have n+ type conductivity by heavily implanting n type dopants. In this embodiment, sidewalls of the mesas may include dielectric spacers 153. The upper mesa region 152G and the lower mesa region 152H may form a n−/n+ mesa diode forming RC-IGBT. In one embodiment, the dielectric spacers 153 may be formed by etching the substrate 151D from the backside 101B using a mask, depositing a dielectric layer and etching the dielectric layer (without mask) by using reactive ion etching (RIE) to form the dielectric spacers 153 on the side walls of the mesas 152. After the dielectric spacer formation, the hole injection regions 154B having p+ type conductivity formed in the grooves 154 by implating dopants as described in the previous embodiments. In the following step, the back metal 156 and the solder 158 is deposited over the backside as described above in FIG. 3A.

FIG. 3E shows an embodiment of the IGBT device 100 constructed as a reverse conducting IGBT device (RC-IGBT) with the backside structure 150E including the mesas 152 and grooves 154 formed by grinding and etching a substrate 151E on which the base region 101 including the above described exemplary front side structures. In one embodiment, a starting silicon wafer may include a base region 101 including an n− type epitaxial layer and a field stop layer 155 of n type conductivity formed on the substrate 151E which may be a n− type conductivity silicon substrate where the mesas 152 and the grooves 154 are formed. In one embodiment, the substrate 151E may be etched down by forming mesas to form n+ electron injection regions. Upper mesa regions 152I may have n− type conductivity; and lower mesa regions 152J may have n+ type conductivity by heavily implanting n type dopants. The upper mesa region 152I and the lower mesa region 152J may form a n−/n+ mesa diode. The hole injection regions 154B having p+ type conductivity formed in the grooves 154 by implating dopants as described in the previous embodiments. In the following step, the back metal 156 and the solder 158 is deposited over the backside 101B, which may complete the RC-IGBT structure.

FIG. 3F shows an embodiment of the IGBT device 100 with the backside structure 150F including the mesas 152 and grooves 154 formed by grinding and etching a substrate 151F on which the base region 101 including the above described exemplary front side structures. In one embodiment, a starting silicon wafer may include a base region 101 including an n− type epitaxial layer and a field stop layer 155, or buffer layer 155, of n type conductivity formed on the substrate 151F which may be a n− type conductivity silicon substrate where the mesas 152 and the grooves 154 are formed. In one embodiment, a hole injection layer 154C having p+ type conductivity may be deposited to conformal cover the mesas 152 and the grooves 154. The hole injection layer 154C may be a poly silicon layer implanted with a p type dopant, such as B, after the deposition. In the following step, the back metal 156 and the solder 158 is deposited over the backside 101B, which completes IGBT device structure.

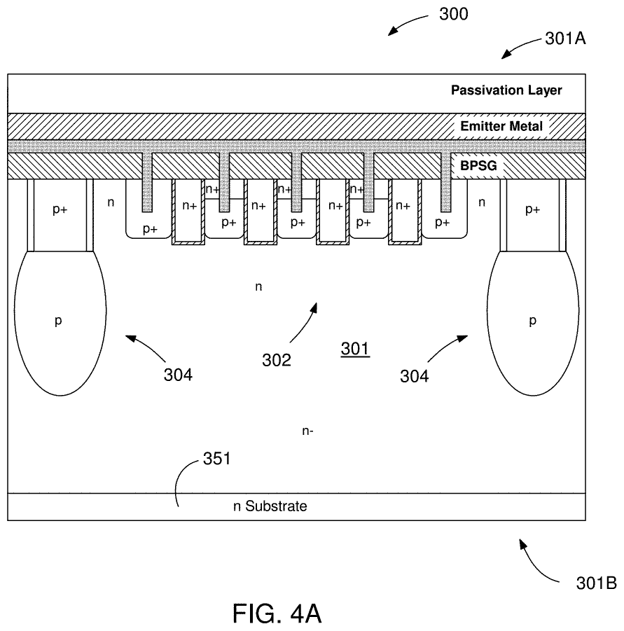

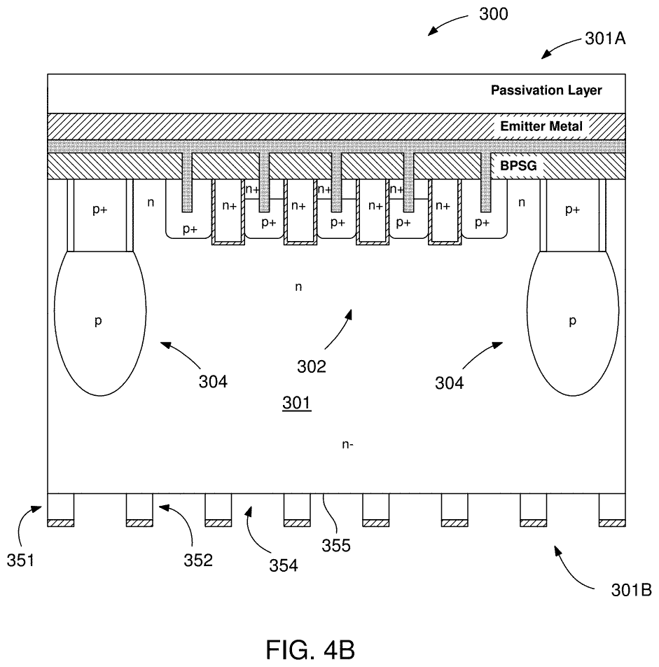

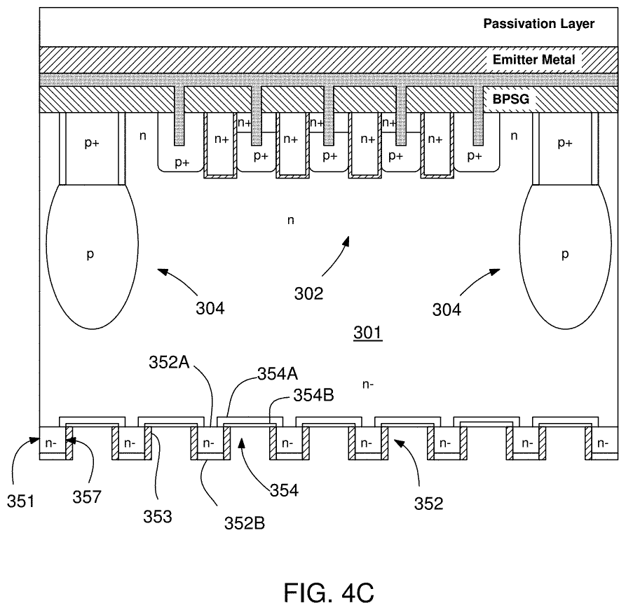

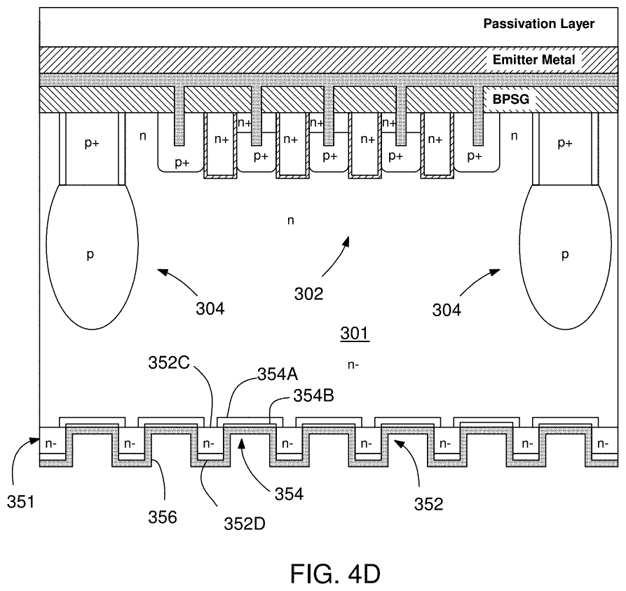

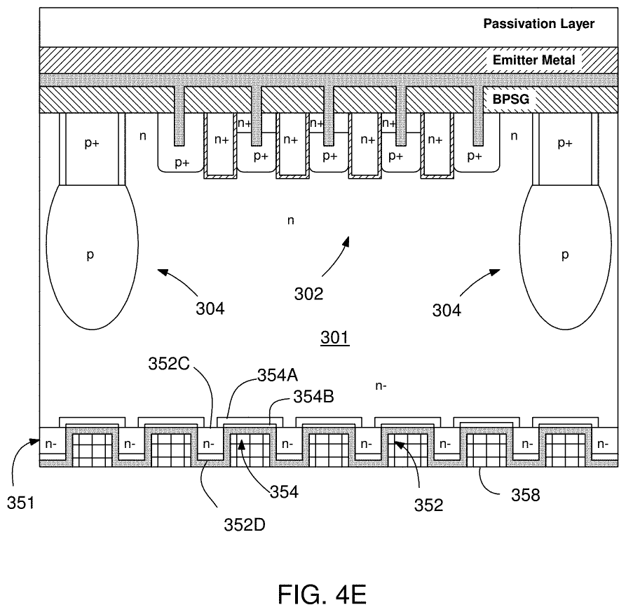

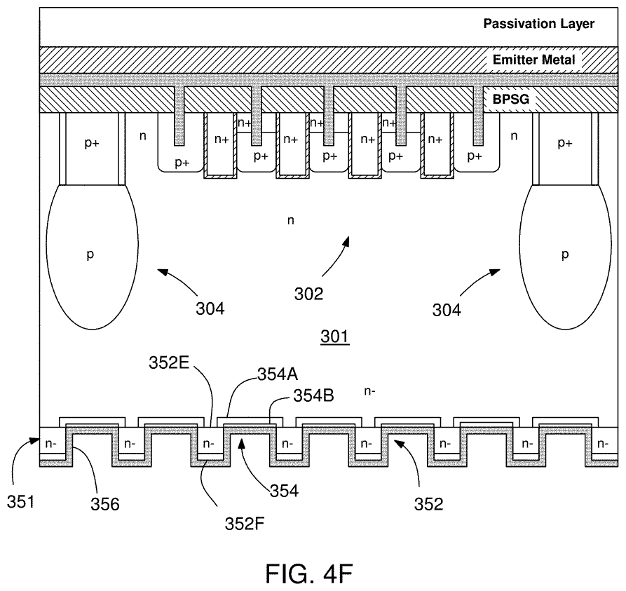

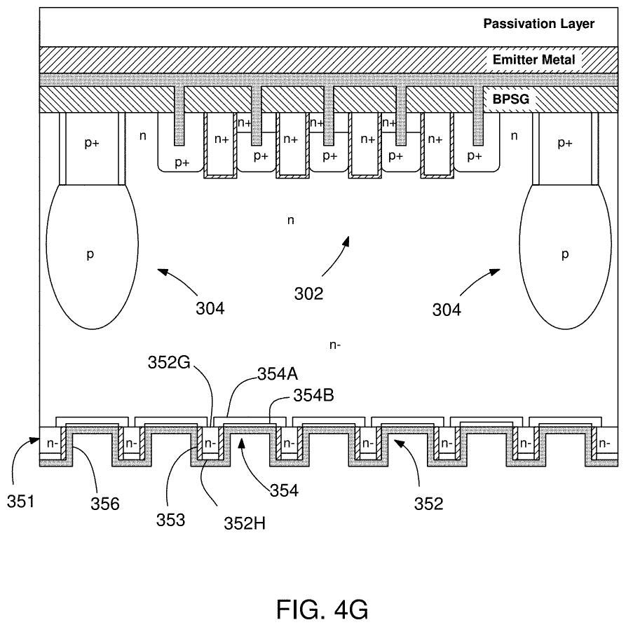

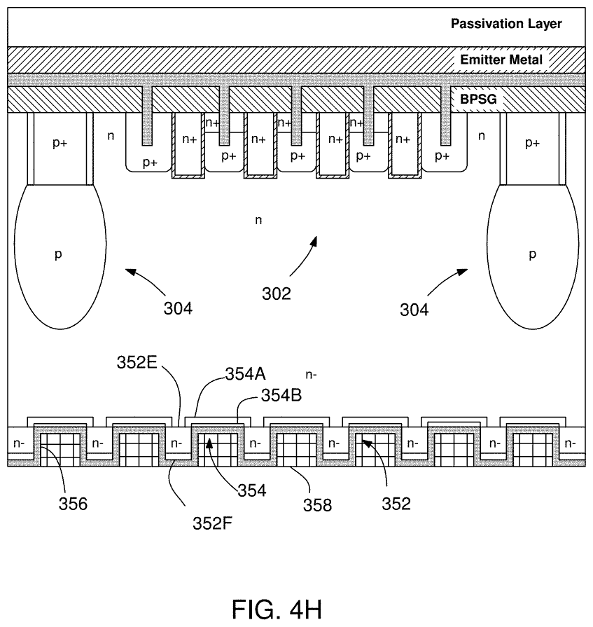

In the following embodiments, various processes to form IGBT with 3D backside structures are described. FIG. 4A through FIG. 6E illustrate methodologies or the process steps to form IGBT devices with 3D backside structures for the wafers having completed front side process steps, i.e., after completing the wafer front side processes. Accordingly, FIGS. 4A-4H generally illustrate an embodiment of a process for forming IGBT devices or RC-IGBT devices with an n− epitaxial layer over an n− substrate having 3D backside structures.

FIG. 4A shows an active IGBT device structure 300 on a wafer including a base region 301, including a drift region, grown over a substrate 351 located at a backside 301B. A front side 301A of the wafer may be completed before the backside process of the present invention. The base region 301 may be a silicon epitaxial layer of n− type conductivity and the substrate 351 may be a silicon substrate or wafer of n type of conductivity. Once the front side process is completed, the substrate 351 may be thinned for the following process steps. In the following embodiments the exemplary front side structure may include the front side structure shown in FIG. 1C.

As shown in FIG. 4B, in the following step, bottom surface is patterned to have an array of mesas 352 and grooves 354 in the substrate 351 using a masking and etching process. The mesas 352 and the grooves 354 may be placed in alternating fashion so that each mesa 352 is separated from the other by a groove 354 including a groove surface 355. After thinning wafer backside by etching using a mask, the etched region from the wafer backside may be 80-100 microns wider at the saw streets around the die areas. Wafer sawing by laser from the top side or the wafer backside may prevent die crack forming during saw process.

As shown in FIG. 4C, before forming the mesas 352 and the grooves 354 by etching the substrate 351, upper mesa regions 352A and lower mesa regions 352B may be formed by doping defined mesa regions on the substrate 351. In this embodiment, the upper mesa regions 352A may have n− type conductivity and the lower mesa regions 352B may have n+ type conductivity by heavily implanting n type dopants. After forming the mesas 352 and the grooves 354, a SiO₂ layer may be deposited using LPCVD process to fill the grooves 354. The SiO₂ layer may be etched using, for example, RIE process, to form dielectric spacers 353, or the oxide spacers 353, on the mesa side walls 357. In the following step, the groove surface 355 may be implanted with dopants to form the buffer region 354A of n conductivity type and a hole injection region of p+ conductivity type extending laterally between the mesas 352 adjacent each groove surface 355. This backside structure may be a backside structure for an RC-IGBT device.

FIG. 4D shows an embodiment of the backside structure for an IGBT device without the dielectric spacers 353 and the upper mesa regions 352C may have n− type conductivity and the lower mesa regions 352B may have p+ type conductivity by heavily implanting n type dopants. A back metal 356, such as a Ti/Ni/Ag layer or an Al/Ti/Ni/Ag layer may be deposited on the mesas 352 and grooves 354. As shown in FIG. 4E, after the back metal process, alternatively the grooves 354 may be filled with a solder layer 358 using a stencil process.

FIG. 4F shows an RC-IGBT with a backside structure. After the wafer thinning process, n dopant implantation may be conducted without using a mask to form n+ lower mesa regions 352F for reverse conduction (electron injection). Afterwards, the backside may be etched via mask and then implanted with an n dopant to form n field stop 354A and implanted with boron for p+ hole injection region 354B. Depositing back metal layer 356 including Al:Ti:Ni:Ag or Ti:Ni:Ag may complete the RC-IGBT forming process.

FIG. 4G shows an RC-IGBT having oxide spacers 353 in a backside structure. After the wafer thinning process, n type backside implantation done without mask to form n+ lower mesa regions 352H for reverse conduction (electron injection) and the rest of the process follows the steps shown in FIGS. 4C-4F.

FIG. 4H shows an RC-IGBT with a backside structure. After the back metal 356 deposition shown above in FIG. 4F, the grooves may be filled with solder 358 using the stencil approach.

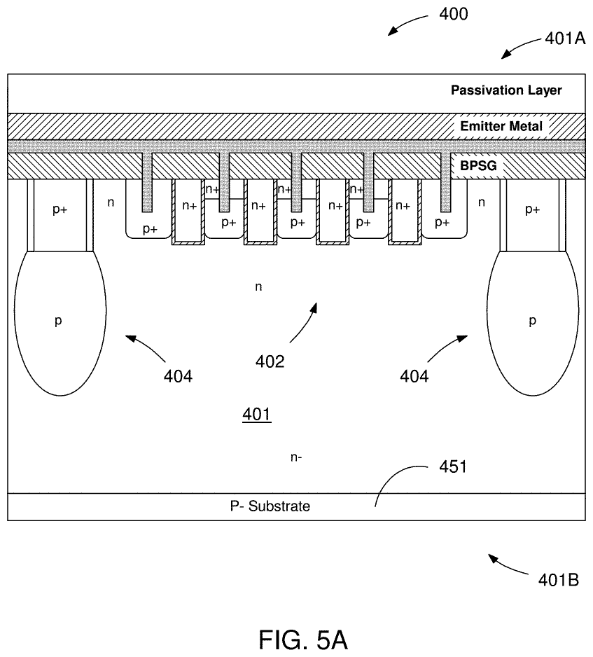

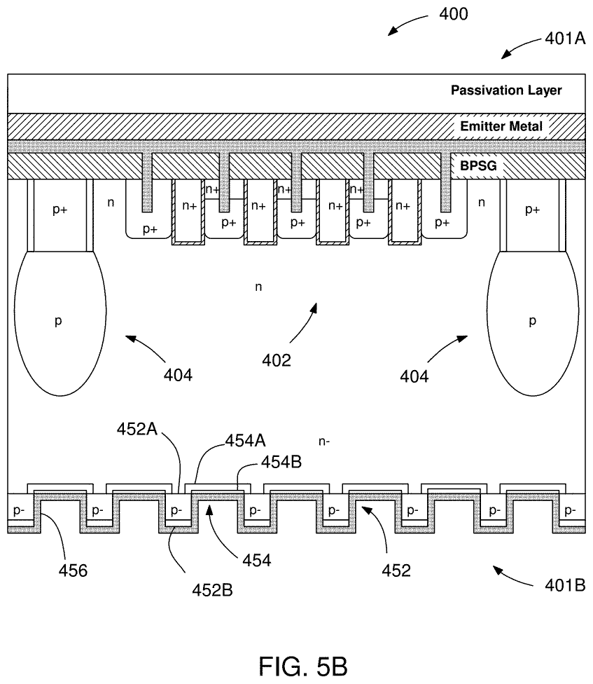

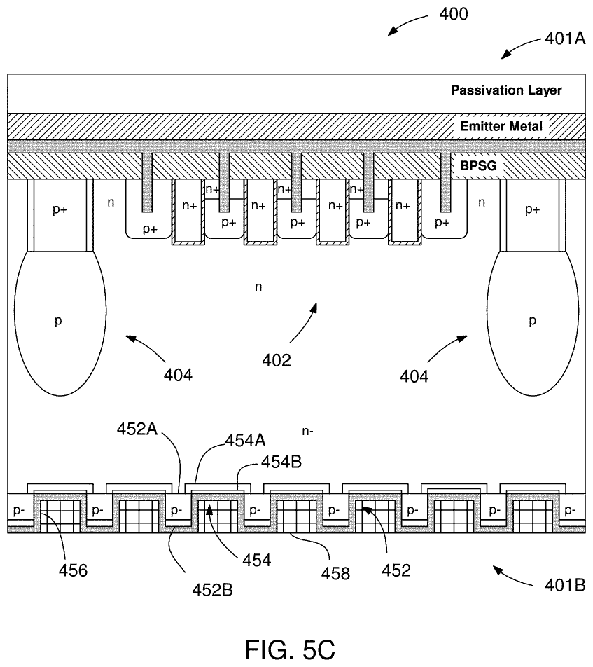

FIGS. 5A-5C illustrate an exemplary implementation of the present invention using a wafer 400 having n− epitaxial layer 401 over a p− substrate 451. FIG. 5A shows an RC IGBT with a backside structure including the p− substrate 451. After the front side process is completed, the p− substrate 451 may be thinned down to required thickness for the breakdown, for example 60 microns for 650V and 120 microns for 1200V IGBT.

FIG. 5B shows an RC-IGBT with a backside structure including mesas 452 with a depletable n buffer/p−/n+ diode. After the backside thinning process, n type dopant is implanted to form n+ lower mesa region 452B (electron injector region). The silicon wafer may be etched using a mask and, in the next step, n buffer layers 454A and p+ hole injection regions 454B may be formed and activated. In the following step, a back metal 456 may be deposited using the process steps described in FIGS. 4B-4F.

FIG. 5C shows an RC-IGBT with a backside structure including depletable n buffer/p−/n+ diode. After depositing the back metal 456, alternatively the grooves 454 may be filled with solder 458 using the stencil approach, and the rest of the process may follow the process steps shown in FIGS. 5B-5F.

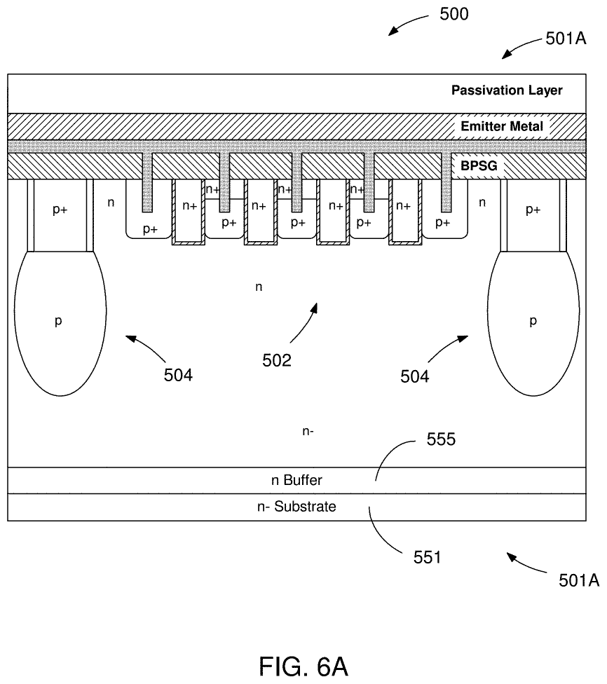

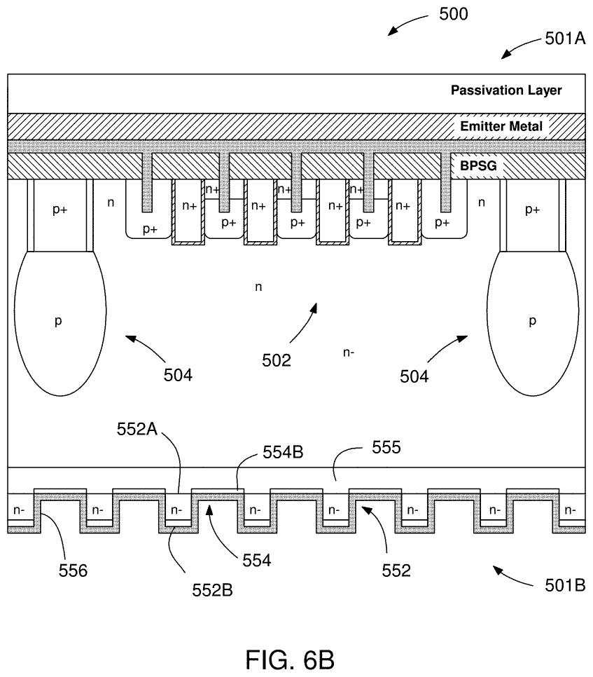

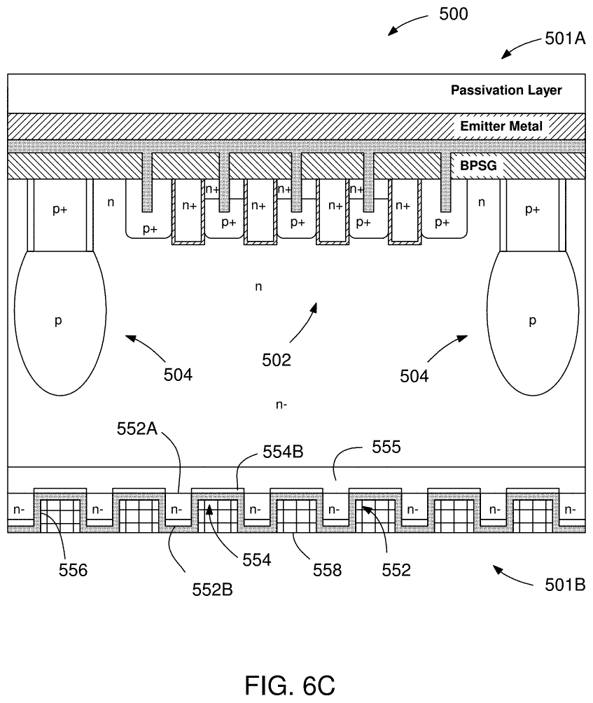

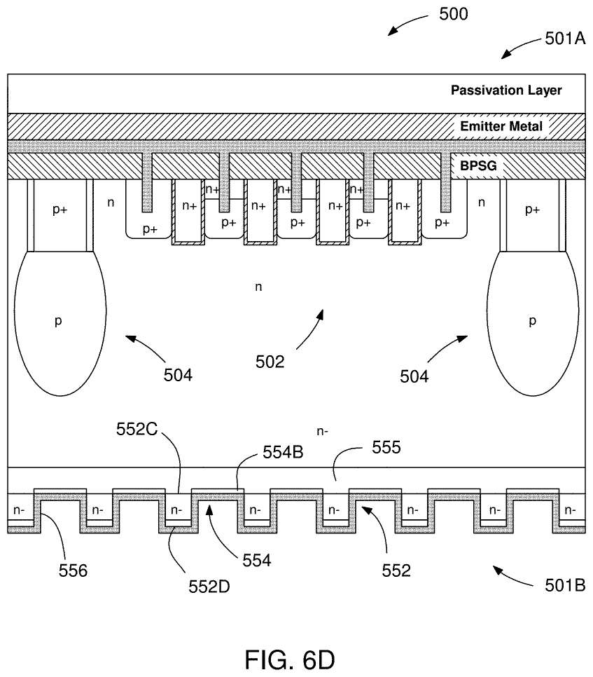

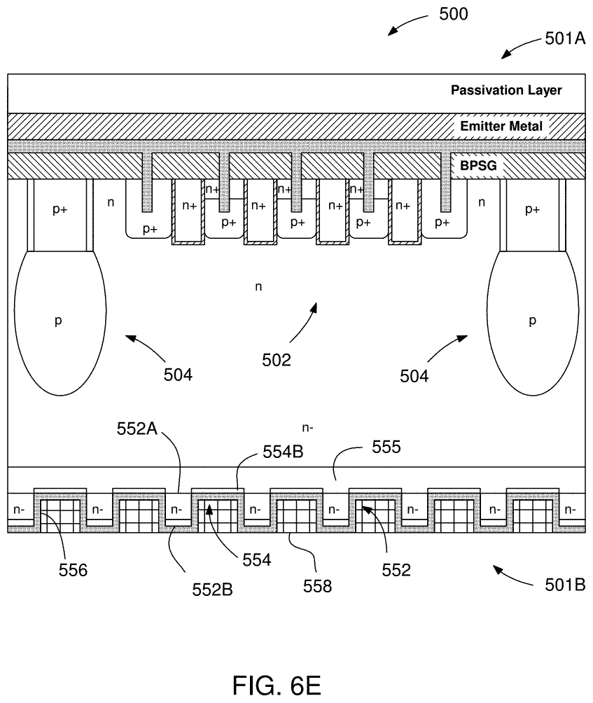

FIGS. 6A-6E illustrate another exemplary implementation of the present invention using a wafer 500 having an n− epitaxial layer/n buffer (field stop layer) 555 over n− substrate 551 respectively. FIG. 6A shows an IGBT with a backside structure including the n buffer layer 555 and the n− substrate 551. After the front side process is completed and the wafer is thinned, the rest of the process follows the process steps described in FIGS. 5B-5C.

FIG. 6B shows an IGBT with a backside structure including the n buffer layer 555 and the n− substrate 551. After the backside etching, p type dopant may be implanted to form p+ hole injector regions 554B and p+ lower mesa regions 552B and activated, which may be followed by a back metal layer 556 including Ti/Ni/Ag layer or Al/Ti/Ni/Ag deposition step. As shown in FIG. 6C, after the back metal deposition process, alternatively, the wafer backside may be filled with a solder 558 using the stencil approach.

FIG. 6D shows an RC-IGBT with a backside structure including the n buffer layer 555 and the n− substrate 551. The process may start with the process steps shown FIG. 6A, and an n type dopant is implanted to form n+ lower mesa regions (electron injection regions). The rest of the process may follow the process steps shown in FIGS. 6B-6C. As shown in FIG. 6E, after the back metal deposition step, alternatively, the wafer backside may be filled with a solder 558 using the stencil approach.

Although the above exemplary embodiments may describe the case of backside processing of wafers having completed front side process, the backside process may be performed after the contact mask and before the surface metallization of the front side, and this is within the scope of this invention.

Although aspects and advantages of the present invention are described herein with respect to certain embodiments, modifications of the embodiments will be apparent to those skilled in the art. Thus, the scope of the present invention should not be limited to the foregoing discussion, but should be defined by the appended claims.

What is claimed is:

1. A vertical insulated gate bipolar transistor (IGBT) device structure, comprising:
a substrate having a top surface and a bottom surface, the substrate having a first conductivity type; and
a drift region of the first conductivity type formed on the top surface,
wherein the bottom surface is patterned to have an array of mesas and grooves in the substrate which are placed in alternating fashion so that each mesa is separated from the other by a groove including a groove surface in which a top buffer region of the first conductivity type and a bottom buried region of a second conductivity type are formed extending laterally between the mesas adjacent each groove surface,
wherein each mesa includes an upper region of the first conductivity type and a lower region of one of the first conductivity type and the second conductivity type, and
wherein each mesa includes dielectric spacers formed on side walls of each mesa.

2. The vertical IGBT device structure of claim 1, wherein the first conductivity type is n type conductivity and the second conductivity type p type conductivity.

3. The vertical IGBT device structure of claim 1, wherein, in each mesa, the upper region includes the first conductivity type with a first dopant concentration and the lower region includes the first conductivity type with a second dopant concentration, wherein the second dopant concentration is higher than the first dopant concentration.

4. The vertical IGBT device structure of claim 3, wherein the first conductivity type of the first dopant concentration is n− type conductivity and the first conductivity type of the second dopant concentration is n+ type conductivity.

5. The vertical IGBT device structure of claim 1, wherein, in each mesa, the upper region includes the first conductivity type with a first dopant concentration and the lower region includes the second conductivity type with a second dopant concentration, wherein the second dopant concentration is higher than the first dopant concentration.

6. The vertical IGBT device structure of claim 5, wherein, the first conductivity type of the first dopant concentration is n− type conductivity and the second conductivity type of the second dopant concentration is p+ type conductivity.

7. The vertical IGBT device structure of claim 1, wherein the top buffer region of the first conductivity type is an n type buffer region and the bottom buried region of the second conductivity type is a p+ hole injection region.

8. The vertical IGBT device structure of claim 1, wherein the array of mesas and grooves are conformally coated with a back metal layer including one of a Ti/Ni/Ag layer and an Al/Ti/Ni/Ag layer.

9. The vertical IGBT device structure of claim 8, wherein a solder material is deposited on the back metal layer to fill the grooves.

10. The vertical IGBT device structure of claim 1, wherein the dielectric spacers include silicon oxide.

11. A process for forming vertical insulated gate bipolar transistor (IGBT) devices, comprising:
finalizing a front surface process on a front surface of a semiconductor wafer, wherein the front surface process forms a front surface structure; and
forming a backside structure on the semiconductor wafer, including:
thinning a back surface of the semiconductor wafer down to a predetermined thickness;
implanting dopants to mesa regions defined on the back surface;
patterning and etching a back surface of the wafer to form an array of mesas and grooves in the back surface which are formed in alternating fashion so that each mesa is separated from the other by a groove including a groove surface;
forming dielectric spacers on side walls of mesas;
implanting dopants of a first conductivity type and a second conductivity type to the back surface to form buried regions inside the groove surfaces;
activating the buried regions and the mesa regions;
depositing a back metal layer conformally coating the mesas and grooves; and
filling the grooves between the mesas with solder material.

12. The process of claim 11, wherein implanting dopants to the mesa regions forms, in each mesa, an upper region of the first conductivity type and a lower region of one of the first conductivity type and the second conductivity type.

13. The process of claim 12, wherein, in each mesa, the upper region includes the first conductivity type with a first dopant concentration and the lower region includes the first conductivity type with a second dopant concentration, wherein the second dopant concentration is higher than the first dopant concentration.

14. The process of claim 13, wherein the first conductivity type of the first dopant concentration is n− type conductivity and the first conductivity type of the second dopant concentration is n+ type conductivity.

15. The process of claim 12, wherein, in each mesa, the upper region includes the first conductivity type with a first dopant concentration and the lower region includes the second conductivity type with a second dopant concentration, wherein the second dopant concentration is higher than the first dopant concentration.

16. The process of claim 15, wherein the first conductivity type of the first dopant concentration is n− type conductivity and the second conductivity type of the second dopant concentration is p+ type conductivity.

17. The process of claim 11, wherein implanting dopants of the first conductivity and the second conductivity to form buried regions forming, in each groove surface, a top buffer region of the first conductivity type and a bottom buried region of a second conductivity type, both of which extend laterally between the mesas adjacent each groove surface, wherein the top buffer region of the first conductivity type is an n type buffer region and the bottom buried region of the second conductivity type is a p+ hole injection region.

18. The process of claim 11, wherein forming the dielectric spacers on side walls of mesas includes: depositing a dielectric layer on the array of mesas and grooves in the back surface, and etching the dielectric layer using reactive ion etching (RIE) to form the dielectric spacers on the side walls of mesas.

19. The process of claim 11, wherein the back metal layer includes one of a Ti/Ni/Ag layer and an Al/Ti/Ni/Ag layer.
